(19) United States
(12) Patent Application Publication
(10) Pub. No.: US 2026/0092984 A1
(43) Pub. Date: Apr. 2, 2026

(54) SECONDARY BATTERY STATE ESTIMATION SYSTEM, SECONDARY BATTERY STATE ESTIMATION METHOD, AND PROGRAM

(71) Applicant: HONDA MOTOR CO., LTD., Tokyo (JP)

(72) Inventors: Takuma Kawahara, Wako-shi (JP); Yuki Sato, Utsunomiya-shi (JP); Koji Sato, Utsunomiya-shi (JP)

(21) Appl. No.: 19/318,434

(22) Filed: Sep. 4, 2025

(30) Foreign Application Priority Data
Sep. 30, 2024 (JP) 2024-171831

(51) Int. Cl. G01R 31/392; G01R 31/367; G01R 31/388

(52) U.S. Cl. CPC G01R 31/392; G01R 31/367; G01R 31/388

(57) ABSTRACT

A system including a secondary battery state estimation device includes an optimization portion that estimates the degradation degree of a secondary battery to be estimated. The optimization portion acquires a plurality of parameters relating to a state of the secondary battery to be estimated based on voltage data which is acquired in the secondary battery to be estimated. Based on a predetermined association between the plurality of parameters and a plurality of voltage regions or a plurality of capacity regions, the optimization portion sequentially performs a predetermined optimization process on at least one parameter exclusively selected from the plurality of parameters for each of the plurality of voltage regions or the plurality of capacity regions.

### CROSS-REFERENCE TO RELATED APPLICATION

Priority is claimed on Japanese Patent Application No. 2024-171831, filed on Sep. 30, 2024, the contents of which are incorporated herein by reference.

### BACKGROUND

### Field of the Invention

The present invention relates to a secondary battery state estimation system, a secondary battery state estimation method, and a program.

### Background

In recent years, in order to ensure that more people have access to affordable, reliable, sustainable, and advanced energy, research and development relating to a secondary battery which contributes to energy efficiency has been conducted.

In the related art, for example, a device is known which acquires an OCV (Open Circuit Voltage) curve indicating a change in an open circuit voltage (OCV) in accordance with a discharge capacity based on the historical data related to the voltage and the current of a battery and an OCP (Open Circuit Potential) curve indicating a change in an open circuit potential (OCP) in accordance with the discharge capacity of each of a positive electrode and a negative electrode (for example, refer to PCT International Publication No. WO 2023/054443 and Japanese Unexamined Patent Application, First Publication No. 2003-48545).

### SUMMARY

In a technique relating to a secondary battery, it is a problem to prevent a decrease in an estimation accuracy of an internal state including an OCV curve or the like, for example, even when the number of parameters of the internal state to be diagnosed increases. For example, in each device of the related art described above, when a uniform diagnosis process is performed on each of a plurality of parameters of the internal state to be diagnosed, there is a possibility that variation (uncertainty) of a diagnosis result increases in association with an increase in the number of parameters.

An aspect of the present invention aims at achieving prevention of a decrease in the estimation accuracy of an internal state even when the number of parameters of the internal state of a secondary battery to be diagnosed increases.

A secondary battery state estimation system according to a first aspect of the present invention includes: a degradation estimation portion that acquires a plurality of parameters relating to a state of a secondary battery to be estimated based on voltage data which is acquired in the secondary battery to be estimated or which is acquired by data acquired in a secondary battery and thereby estimates the degradation degree of the secondary battery to be estimated, wherein based on a predetermined association between the plurality of parameters and a plurality of voltage regions or a plurality of capacity regions, the degradation estimation portion sequentially acquires at least one parameter exclusively selected from the plurality of parameters for each of the plurality of voltage regions or the plurality of capacity regions.

A second aspect is the secondary battery state estimation system according to the first aspect described above, wherein the degradation estimation portion may associate each of the plurality of parameters with a voltage region or a capacity region in which each of the parameters develops a capacity characteristic among the plurality of voltage regions or the plurality of capacity regions as the predetermined association.

A third aspect is the secondary battery state estimation system according to the first or second aspect described above, wherein when a number of parameters associated with a first voltage region by the predetermined association is less than the number of parameters associated with a second voltage region that is different from the first voltage region, the degradation estimation portion may acquire, in the first voltage region before the second voltage region, a parameter associated with the first voltage region.

A fourth aspect is the secondary battery state estimation system according to the first or second aspect described above, wherein when a number of parameters associated with a first capacity region by the predetermined association is less than a number of parameters associated with a second capacity region that is different from the first capacity region, the degradation estimation portion may acquire, in the first capacity region before the second capacity region, a parameter associated with the first capacity region.

A fifth aspect is the secondary battery state estimation system according to the first aspect described above, wherein the plurality of parameters may include a parameter relating to the degradation degree of silicon contained in a negative electrode of the secondary battery to be estimated.

A secondary battery state estimation method according to a sixth aspect of the present invention is a method performed by an electronic apparatus including a process portion that estimates a degradation degree of a secondary battery to be estimated, the method including: acquiring a plurality of parameters relating to a state of the secondary battery to be estimated based on voltage data which is acquired in the secondary battery to be estimated or which is acquired by data acquired in a secondary battery; and based on a predetermined association between the plurality of parameters and a plurality of voltage regions or a plurality of capacity regions, sequentially acquiring at least one parameter exclusively selected from the plurality of parameters for each of the plurality of voltage regions or the plurality of capacity regions.

A seventh aspect of the present invention is a computer-readable non-transitory recording medium that records a program causing a computer of an electronic apparatus including a process portion that estimates a degradation degree of a secondary battery to be estimated to execute: acquiring a plurality of parameters relating to a state of the secondary battery to be estimated based on voltage data which is acquired in the secondary battery to be estimated or which is acquired by data acquired in a secondary battery; and based on a predetermined association between the plurality of parameters and a plurality of voltage regions or a plurality of capacity regions, sequentially acquiring at least one parameter exclusively selected from the plurality of parameters for each of the plurality of voltage regions or the plurality of capacity regions.

According to the first aspect described above, by including the degradation estimation portion that sequentially acquires the parameter exclusively selected from the plurality of parameters, even when the number of parameters of an internal state of the secondary battery to be diagnosed increases, it is possible to prevent a decrease in an estimation accuracy of the internal state. For example, compared to the case where all of the plurality of parameters are acquired in a collective manner instead of a gradual manner, each parameter can be uniquely acquired, and it is possible to stabilize each parameter and improve the estimation accuracy.

In the case of the second aspect described above, since each parameter is acquired for each voltage region or each capacity region where the capacity characteristic of each parameter is developed, it is possible to improve the estimation accuracy of each parameter.

In the case of the third or fourth aspect described above, since a region to be processed is exclusively selected from the plurality of voltage regions or the plurality of capacity regions associated with the plurality of parameters in the order of a smaller number of overlapping of different parameters, it is possible to stabilize each parameter and improve the estimation accuracy.

In the case of the fifth aspect described above, it is possible to improve the estimation accuracy of the degradation degree with respect to silicon in which the capacity characteristic develops at a discharge end stage (or a degradation end stage).

According to the sixth or seventh aspect described above, by sequentially acquiring the parameter exclusively selected from the plurality of parameters, even when the number of parameters of an internal state of the secondary battery to be diagnosed increases, it is possible to prevent a decrease in an estimation accuracy of the internal state. For example, compared to the case where all of the plurality of parameters are acquired in a collective manner instead of a gradual manner, each parameter can be uniquely acquired, and it is possible to stabilize each parameter and improve the estimation accuracy.

### BRIEF DESCRIPTION OF THE DRAWINGS

FIG. 1 is a block diagram showing the functional configuration of a system including a secondary battery state estimation device in an embodiment of the present invention.

FIG. 2 is a view showing an example of an OCV curve acquired based on an OCP curve of each of a positive electrode and a negative electrode by an optimization portion of the secondary battery state estimation device in the embodiment of the present invention.

FIG. 3 is a view showing an example of a flow of information in a parameter optimization process by the optimization portion of the secondary battery state estimation device in the embodiment of the present invention.

FIG. 4 is a view showing an example of a parameter in each of a positive electrode OCP curve and a negative electrode OCP curve set by the secondary battery state estimation device in the embodiment of the present invention.

FIG. 5 is a flowchart showing a process performed by the secondary battery state estimation device in the embodiment of the present invention.

FIG. 6 is a view showing an example of a voltage region that contributes to a shape change of the OCV curve in each of a plurality of parameters relating to the state of the secondary battery according to the embodiment of the present invention.

### DESCRIPTION OF EMBODIMENTS

Hereinafter, a secondary battery state estimation system, a secondary battery state estimation method, and a program according to an embodiment of the present invention will be described with reference to the accompanying drawings.

A secondary battery according to an embodiment is, for example, detachably or fixedly arranged in various electric apparatuses.

Examples of various electric apparatuses include an electric vehicle, an electric movable body, an electric machine, an electric power source device, and the like. Examples of the electric vehicle include an electric automobile including a rotary electric machine driven by electric power of a secondary battery as a power source, a saddle riding vehicle, a kick skater, a hybrid vehicle by a combination of a rotary electric machine and an internal combustion engine, a fuel cell vehicle by a combination of a secondary battery and a fuel cell, and the like. Examples of the electric movable body include a robot, a movable work machine, a flying vehicle, a movable body on water, an underwater movable body, and the like. Examples of the electric machine include a construction machine including a rotary electric machine as a power source and the like. Examples of the electric power source device include a stationary or mobile electric power source device that performs discharging and charging of a secondary battery, an exchange device that supplies (provides) and receives a secondary battery for a user in a so-called battery share service, or the like.

Various electric apparatuses may include, for example, an external charging function of being charged by an external electric power source (an external DC electric power source and an external AC electric power source) such as a PHV (Plug-in Hybrid Vehicle) or a PHEV (Plug-in Hybrid Electric Vehicle). Various electric apparatuses may include, for example, a function of supplying electric power to the outside by the electric power of the secondary battery. Further, the rotary electric machine mounted on the electric vehicle may transfer electric power to and from the secondary battery, for example, by a regeneration operation using rotation power input from a wheel side, electric power generation by power input from an internal combustion engine, or the like in addition to a power running operation.

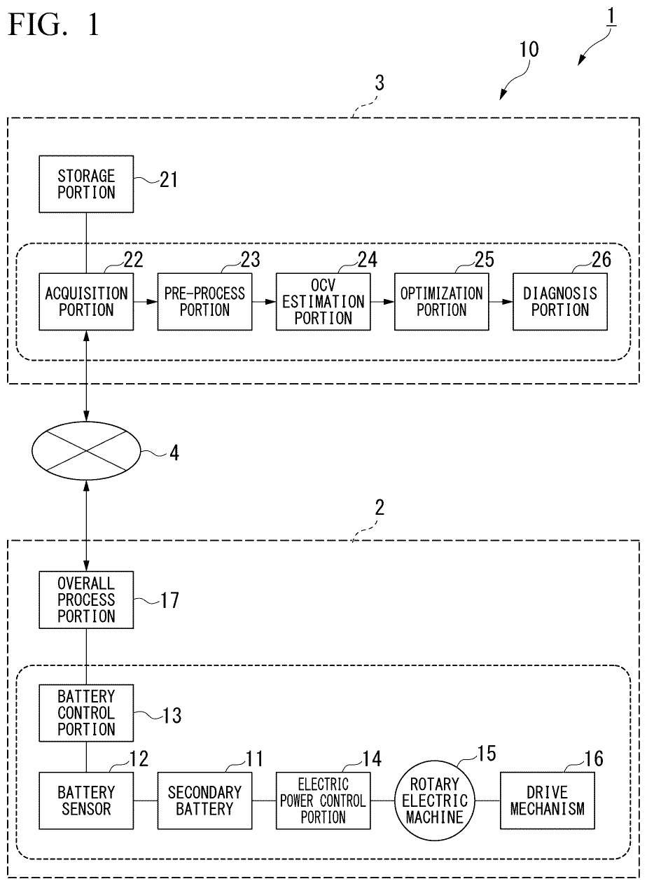

FIG. 1 is a block diagram showing a functional configuration of a system 1 including a secondary battery state estimation device 10 of the embodiment.

As shown in FIG. 1, a system 1 (a secondary battery state estimation system, an electronic apparatus) of the embodiment includes, for example, a vehicle 2 and a server 3. The vehicle 2 and the server 3 are connected to each other, for example, via a wired or wireless communication network (network) 4. Examples of the network 4 include the Internet, a mobile communication network, a LAN (Local Area Network), a WAN (Wide Area Network), and the like. The LAN is, for example, a wired LAN (Local Area Network) of a predetermined standard such as Ethernet or a wireless LAN of various standards such as Wi-Fi and Bluetooth (registered trademark).

The secondary battery state estimation device 10 of the embodiment is constituted, for example, of the server 3.

The vehicle 2 includes, for example, a secondary battery 11, a battery sensor 12, a battery control portion 13, an electric power control portion 14, a rotary electric machine 15, a drive mechanism 16, and an overall process portion 17.

The secondary battery 11 is, for example, a variety of batteries that repeat charging and discharging such as a lithium ion battery, a sodium ion battery, a nickel hydride battery, or the like. The electrolyte of the secondary battery 11 is, for example, a non-aqueous electrolyte such as a liquid, a solid, or a polymer.

A positive electrode active material that constitutes a positive electrode of the secondary battery 11 is, for example, a metal oxide containing lithium ions or the like in the case of a lithium ion battery.

The metal oxide containing lithium ions is, for example, a simple substance of a complex oxide by lithium and a metal such as nickel, cobalt, manganese, and aluminum, a mixture of a plurality of different complex oxides, or the like. The complex oxides are classified into a bedded salt type, a spinel type, and an olivine type, for example, from the viewpoint of a crystal structure. Examples of the complex oxides of the bedded salt type include lithium cobalt oxide (LCO: LiCoO₂), nickel-cobalt-manganese oxide (NCM: Li(NiₓCo_{y}Mn_{z})O₂), nickel-cobalt-aluminum oxide (NCA: LiNiₓCo_{y}AlₓO₂), and the like. Examples of the complex oxides of the spinel type include lithium manganese oxide (LMO: LiMn₂O₄), lithium nickel-manganese oxide (LNMO: LiNiₓMn_{y}O₄), and the like. Examples of the complex oxides of the olivine type include lithium iron phosphate (LFP: LiFePO₄), lithium manganese iron phosphate (LMFP: LiMnxFe₍₁₋ₓ₎PO₄), and the like.

A negative electrode active material that constitutes a negative electrode of the secondary battery 11 is formed of, for example, a carbon material, an oxide material, a mixed material, or the like in the case of a lithium ion battery. Examples of the carbon material include graphite (black lead), hard carbon (non-graphitizable carbon), and the like. Examples of the oxide material include lithium titanate (LTO: Li₄Ti₅O₁₂) and the like. Examples of the mixed material include a mixed material of a metal material and a carbon material such as Si and Sn and the like, such as a mixed material of graphite and a silicon oxide (SiOₓ) or the like.

The battery sensor 12 includes, for example, various sensors that detect the state of the secondary battery 11. The battery sensor 12 includes, for example, a voltage sensor, a current sensor, a temperature sensor, and the like. The battery sensor 12 outputs, for example, signals of various detection values of a voltage, a current, a temperature, and the like relating to the state of the secondary battery 11.

The battery control portion 13 is, for example, a so-called BMU (Battery Management Unit) and monitors and controls the state of the secondary battery 11. The battery control portion 13 is, for example, a software function unit that functions by a predetermined program being executed by a processor such as a CPU (Central Processing Unit). The software function unit is an ECU (Electronic Control Unit) including a processor such as a CPU, a ROM (Read Only Memory) that stores a program, a RAM (Random Access Memory) that temporarily stores data, and an electronic circuit such as a timer. At least part of the battery control portion 13 may be an integrated circuit such as an LSI (Large Scale Integration).

The battery control portion 13 stores, for example, information relating to the secondary battery 11, a predetermined program, and the like. The information relating to the secondary battery 11 includes, for example, identification information such as an ID (Identifier) exclusively assigned to the secondary battery 11, the manufacturing date and time, the capacity of an initial state, information relating to the state of the secondary battery 11 based on an output of the battery sensor 12, and the like. The information relating to the state of the secondary battery 11 includes, for example, information relating to the current state such as a charging state such as a charging rate, a remaining capacity (SOC: State Of Charge), or an electric power amount, history of charging and discharging such as the number of times of charging, a voltage, and a temperature, information relating to the current degradation state such as the degree of degradation, information relating to the presence or absence of abnormality, and the like.

The electric power control portion 14 is connected to the secondary battery 11 and the rotary electric machine 15. The electric power control portion 14 includes, for example, a voltage converter such as a DC-DC converter that converts a voltage in DC and an electric power converter such as a DC-AC converter that converts electric power between DC and AC. The electric power control portion 14 controls electric power transfer between the secondary battery 11 and the rotary electric machine 15, for example, based on a control signal received from the overall process portion 17.

The rotary electric machine 15 is, for example, a three-phase AC brushless DC motor or the like. The rotary electric machine 15 generates rotation power by performing a power running operation by electric power that is supplied from the electric power control portion 14. For example, when the rotary electric machine 15 is connected to a wheel of the vehicle 2, the rotary electric machine 15 generates a travel drive force by performing the power running operation by the electric power that is supplied from the electric power control portion 14. The rotary electric machine 15 may generate electric power by performing a regeneration operation by rotation power that is input from the wheel side of the vehicle 2. When the rotary electric machine 15 is connected to an internal combustion engine of the vehicle 2, the rotary electric machine 15 may generate electric power by the power of the internal combustion engine.

The drive mechanism 16 is a power transmission mechanism connected to a rotor of the rotary electric machine 15. The drive mechanism 16 includes, for example, equipment elements such as a gear, a belt, and a chain. The drive mechanism 16 transmits, for example, power between the rotary electric machine 15 and the wheel of the vehicle 2. The drive mechanism 16 may include, for example, a regulation mechanism that regulates power transmission such as an electric parking brake that stops rotation of the wheel or a drive shaft and a parking lock mechanism.

The overall process portion 17 overall controls the operation of the vehicle 2. The overall process portion 17 includes, for example, a software function unit. At least part of the overall process portion 17 may include an integrated circuit.

The overall process portion 17 includes, for example, an input-output section and a communication section.

The input-output section includes, for example, various operation devices such as a keyboard, a touch panel, a mouse, and a button, a display device such as a liquid crystal display or an organic EL (Electro Luminescence) display, and various input-output devices such as a microphone for voice input and a speaker for sound output. The input-output section receives, for example, an operation by an operator such as a user or an input operation which is a voice input and outputs a signal in accordance with the input operation.

The communication section performs transmission and reception of various information to and from the server 3 via the network 4. The communication section transmits to the server 3, for example, information by a combination of information such as date and time, identification information of the vehicle 2 or the secondary battery 11, and information relating to the secondary battery 11 received from the battery control portion 13.

The server 3 includes, for example, a software function unit. At least part of the overall process portion 17 may include an integrated circuit. The server 3 includes, for example, a storage portion 21, an acquisition portion 22, a pre-process portion 23, an OCV estimation portion 24, an optimization portion 25 (degradation estimation portion, process portion), and a diagnosis portion 26.

The storage portion 21 stores, for example, various information such as information relating to the secondary battery 11 acquired by the server 3 in advance or received by the server 3 from the vehicle 2 at an appropriate timing and information generated by the server 3, and a predetermined program.

The acquisition portion 22 acquires, for example, time series data of a voltage, a current, a temperature, and the like of the secondary battery 11 from the vehicle 2. The voltage of the secondary battery 11 is, for example, a closed circuit voltage (CCV). The acquisition portion 22 acquires a discharge capacity (discharge amount), for example, by integrating the time series data of the current.

The pre-process portion 23 performs, for example, a process such as cleansing and filtering of the time series data acquired by the acquisition portion 22. The pre-process portion 23 excludes, for example, data in which a loss, an abnormality, or the like occurs from the time series data.

The OCV estimation portion 24 estimates an open circuit voltage (OCV, voltage data) of a secondary battery 11 to be estimated and acquires history data of the open circuit voltage (OCV) in the secondary battery 11 as described below.

The OCV estimation portion 24 extracts, for example, data in which a change caused by charging and discharging of the secondary battery 11 is equal to or less than a predetermined threshold value from the time series data processed by the pre-process portion 23. The OCV estimation portion 24 sets, for example, data indicating the change of the predetermined threshold value or less as data at a timing when a closed circuit voltage (CCV, voltage data) can be regarded as the open circuit voltage (OCV).

The OCV estimation portion 24 may estimate the open circuit voltage (OCV) of the secondary battery 11 to be estimated, for example, by using an appropriate machine learning model from the time series data processed by the pre-process portion 23. The OCV estimation portion 24 constructs a machine learning model that outputs the open circuit voltage (OCV) or voltage data relating to the open circuit voltage (OCV), for example, by using data acquired based on a test performed on the secondary battery 11 in which the degradation state is known, a simulation performed on a predetermined model of the secondary battery 11, or the like. The OCV estimation portion 24 inputs data of a current and a closed circuit voltage (CCV) at an appropriate timing detected in the secondary battery 11 to be estimated to the machine learning model and thereby acquires an open circuit voltage (OCV) at an arbitrary timing of the secondary battery 11 to be estimated.

The OCV estimation portion 24 may estimate the open circuit voltage (OCV) of the secondary battery 11 to be estimated, for example, by using an appropriate equivalent circuit model.

The OCV estimation portion 24 stores the acquired open circuit voltage (OCV) at an arbitrary timing (date and time or the like) in the storage portion 21 as history data of the open circuit voltage (OCV).

The history data is, for example, data acquired in an appropriate period and is not limited to a series of data such as the time series data.

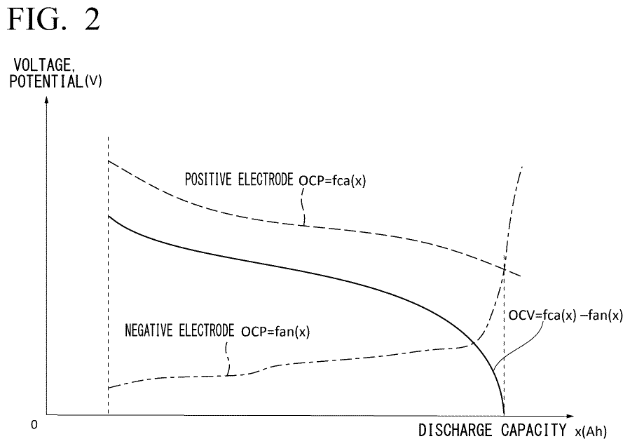

FIG. 2 is a view showing an example of an OCV curve acquired based on an OCP curve of each of a positive electrode and a negative electrode by the optimization portion 25 of the secondary battery state estimation device 10 in the embodiment. As shown in FIG. 2, the optimization portion 25 acquires an OCP curve indicating a change in an open circuit potential (OCP) in accordance with a discharge capacity x (Ah) of each of the positive electrode and the negative electrode of the secondary battery 11, for example, based on a plurality of parameters relating to the state of the secondary battery 11. The optimization portion 25 acquires a positive electrode OCP curve (=fca (x)) and a negative electrode OCP curve (=fan (x)), for example, by causing a plurality of parameters to act on an OCP curve (reference OCP curve) stored in advance in the storage portion 21.

The reference OCP curve stored in the storage portion 21 is acquired, for example, by a test performed in advance, a simulation by an appropriate model, or the like. The reference OCP curve is, for example, an OCP curve of a simple substance of each active material constituting each of the positive electrode and the negative electrode of the secondary battery 11. The optimization portion 25 estimates the OCV curve (=fca (x)−fan (x)) indicating the change in the open circuit voltage (OCV) in accordance with the discharge capacity x (Ah), for example, based on the difference between the positive electrode OCP curve (=fca (x)) and the negative electrode OCP curve (=fan (x)).

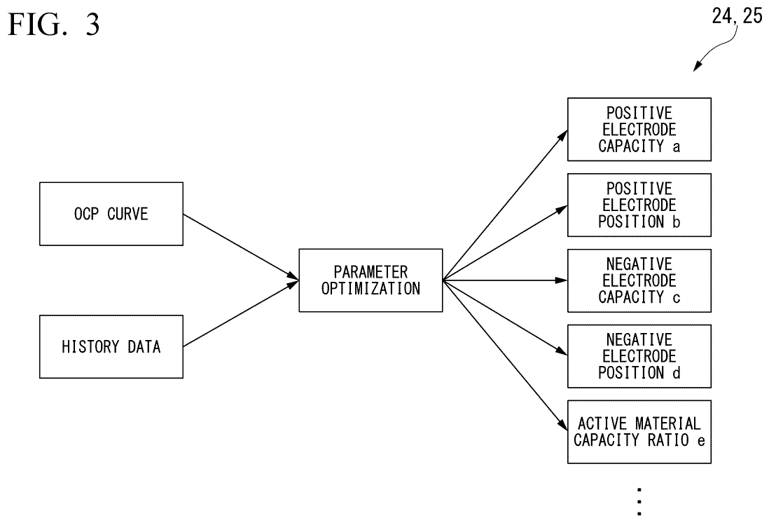

FIG. 3 is a view showing an example of a flow of information in a parameter optimization process by the optimization portion 25 of the secondary battery state estimation device 10 in the embodiment.

As shown in FIG. 3, the plurality of parameters relating to the state of the secondary battery 11 include, for example, a positive electrode capacity a, a positive electrode position b, a negative electrode capacity c, a negative electrode position d, an active material capacity ratio e, and the like. The active material capacity ratio e is, for example, a ratio set by a capacity of each active material with respect to an electrode (each of the positive electrode and the negative electrode) constituted by a mixing of a plurality of active materials such as a mixed material or the like. A parameter optimization process performed by the optimization portion 25 includes, for example, generation of an OCV curve based on the positive electrode OCP curve (=fca (x)) and the negative electrode OCP curve (=fan (x)) and optimization (reconfiguring) of the plurality of parameters. The optimization portion 25 optimizes the plurality of parameters relating to the state of the secondary battery 11, for example, based on the OCV curve estimated based the OCP curve and the history data of the secondary battery 11.

The optimization portion 25 performs, for example, a predetermined optimization process based on an error function indicating an error between the OCV curve estimated based on the OCP curve of each of the positive electrode and the negative electrode and the history data of the open circuit voltage (OCV) of the secondary battery 11. The error function is, for example, a weighted mean square error (Weighted RMSE), a weighted mean absolute error (Weighted MAE), or the like. The predetermined optimization process is, for example, a local optimization algorithm such as a BFGS method, a conjugate gradient method, and a COBYLA method, a global optimization algorithm such as a genetic algorithm, a differential evolution method, a SHGO method, and an annealing method, or the like. In the parameter optimization process, for example, reconfiguring of the plurality of parameters by the optimization portion 25, acquisition of the positive electrode OCP curve and the negative electrode OCP curve, and estimation of the OCV curve are repeated so that the value of the error function becomes equal to or less than a predetermined value.

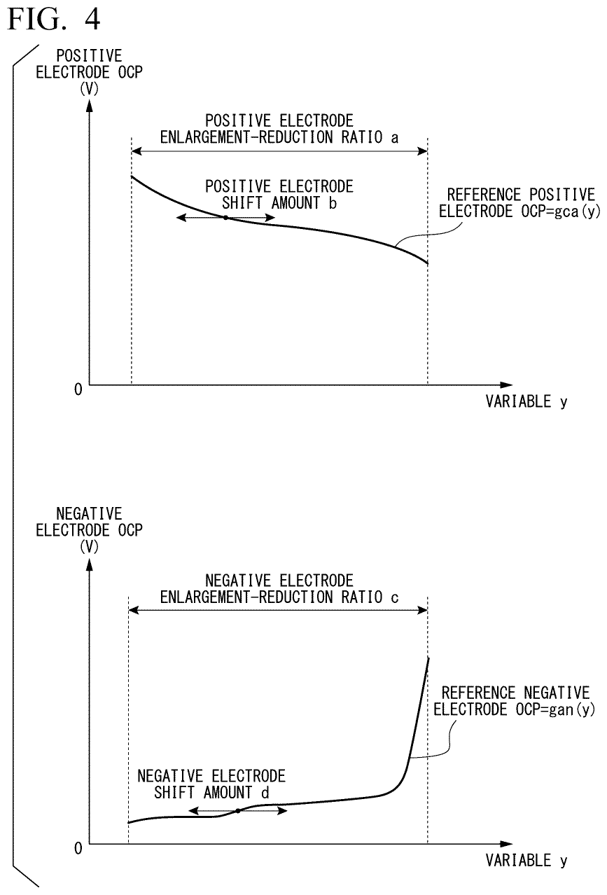

FIG. 4 is a view showing an example of a parameter in each of a positive electrode OCP curve and a negative electrode OCP curve set by the secondary battery state estimation device 10 in the embodiment.

The parameter shown in FIG. 4 generates a positive electrode OCP curve (=fca (x)) and a negative electrode OCP curve (=fan (x)) which are mathematical models in which a discharge capacity x (Ah) is a variable, for example, by acting on a reference positive electrode OCP curve (=gca (y)) and a reference negative electrode OCP curve (=gan (y)) which are predetermined mathematical models by a dimensionless variable y. Each of the reference positive electrode OCP curve and the reference negative electrode OCP curve shown in FIG. 4 is a composite OCP curve obtained by an OCP curve of a simple substance of each active material, for example, in the case of an electrode constituted by a mixing of a plurality of active materials such as a mixed material or the like.

The parameters shown in FIG. 4 are, for example, a positive electrode capacity a and a positive electrode position b that convert the reference positive electrode OCP curve into a positive electrode OCP curve, and a negative electrode capacity c and a negative electrode position d that convert the reference negative electrode OCP curve into a negative electrode OCP curve.

The positive electrode capacity a and the positive electrode position b are, for example, a positive electrode enlargement-reduction ratio a relating to the size of a width of the discharge capacity and a positive electrode shift amount b relating to the position in a discharge capacity direction and convert a dimensionless variable y into a discharge capacity x (=ax y+b). The negative electrode capacity c and the negative electrode position d are, for example, a negative electrode enlargement-reduction ratio c relating to the size of a width of the discharge capacity and a negative electrode shift amount d relating to the position in the discharge capacity direction and convert the dimensionless variable y into the discharge capacity x (=c× y+d).

For example, based on a predetermined association between the plurality of parameters and a plurality of voltage regions or a plurality of capacity regions, the optimization portion 25 performs the predetermined optimization process on the plurality of parameters in a gradual manner. The predetermined association is, for example, an association between each of the plurality of parameters and a voltage region or a capacity region (development region) in which each parameter develops a capacity characteristic. The development region of each parameter is, for example, a region of a voltage or a capacity where the shape of the estimated OCV curve changes when each parameter corresponding to various degradation states of the secondary battery 11 is independently changed. For example, when the development region is set based on the presence or absence of a shape change of the OCV curve associated with a change of each parameter, the presence or absence of the shape change may be determined based on an appropriate threshold value set for the degree of the shape change of the OCV curve. The development region of each parameter may be acquired at each execution of a series of optimization processes, for example, based on the OCP curve (reference OCP curve) stored in the storage portion 21 in advance, or may be acquired in advance and stored in the storage portion 21.

The optimization portion 25 acquires a region (overlapping region) in which overlapping states of the development regions of the plurality of parameters are different from each other, for example, in the voltage region or the capacity region. The overlapping state is, for example, the number of parameters that overlap or the like. The optimization portion 25 sequentially performs the predetermined optimization process on at least one parameter exclusively selected from the plurality of parameters, for example, for respective overlapping regions. For example, the optimization portion 25 exclusively selects an overlapping region to be processed from a plurality of overlapping regions in the order of the smaller number of overlapping of different parameters. For example, the optimization portion 25 sequentially performs the predetermined optimization process on each overlapping region in which the number of overlapping is the smallest and which is exclusively selected from the plurality of overlapping regions.

For example, when the number of parameters in a first overlapping region among the plurality of overlapping regions is less than the number of parameters in a second overlapping region that is different from the first overlapping region, the optimization portion 25 performs the predetermined optimization process in the first overlapping region before the second overlapping region.

The diagnosis portion 26 acquires a diagnosis value relating to the degradation state of the secondary battery 11, for example, based on the OCV curve estimated based on the OCP curve after the optimization of the plurality of parameters by the optimization portion 25. The diagnosis portion 26 sets the ratio of a full charge capacity at the time of degradation as a SOH (State of Health) diagnosis value, for example, assuming that the full charge capacity in the initial state of the secondary battery 11 is 100%. The full charge capacity at the time of degradation is, for example, the difference between the discharge capacity at a full discharge voltage and the discharge capacity at a full charge voltage acquired based on the OCV curve.

The diagnosis portion 26 associates, for example, an acquired SOH diagnosis value with the date and time when the OCV curve is obtained by the optimization portion 25 and thereby stores history data of the SOH diagnosis value in the storage portion 21.

### (Operation of Secondary Battery State Estimation Device)

Hereinafter, an operation of the secondary battery state estimation device 10 of the embodiment, particularly a process performed by the optimization portion 25 is described.

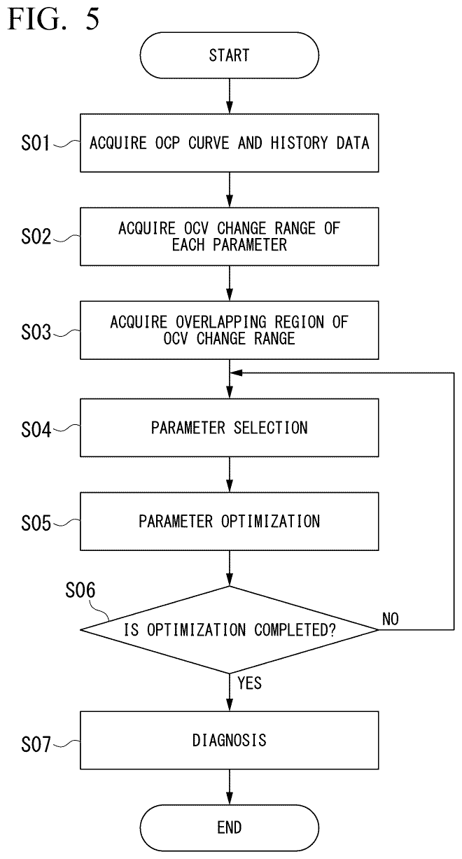

FIG. 5 is a flowchart showing a process performed by the secondary battery state estimation device 10 in the embodiment. A series of processes from Step S01 to Step S07 shown in FIG. 5 are repeatedly performed at an appropriate timing.

As shown in FIG. 5, first, the optimization portion 25 acquires, for example, an OCP curve (reference OCP curve) of a simple substance of each active material constituting each of the positive electrode and the negative electrode of the secondary battery 11. The optimization portion 25 acquires, for example, a positive electrode OCP curve (=fca (x)) and a negative electrode OCP curve (=fan (x)) based on the reference OCP curve and the latest plurality of parameters. The optimization portion 25 estimates an OCV curve (=fca (x)−fan (x)), for example, based on the difference between the positive electrode OCP curve (=fca (x)) and the negative electrode OCP curve (=fan (x)). The optimization portion 25 acquires, for example, history data of the secondary battery 11 (Step S01).

Next, the optimization portion 25 acquires, for example, a development region (OCV change range) of each of the plurality of parameters, that is, a region of a voltage or a capacity where the shape of the OCV curve changes in association with a change of each parameter (Step S02).

Next, the optimization portion 25 acquires, for example, an overlapping region in which the overlapping states of the development regions of the plurality of parameters are different from each other, that is, an overlapping region of the OCV change range (Step S03).

Next, the optimization portion 25 selects, for example, an overlapping region in which the number of overlapping of the parameter is the smallest exclusively from a plurality of overlapping regions. The optimization portion 25 selects, for example, a parameter included in the selected overlapping region exclusively from the plurality of parameters (Step S04).

Next, the optimization portion 25 searches and optimizes each selected parameter, for example, by a predetermined optimization process based on the estimated OCV curve and the history data of the secondary battery 11 in the selected overlapping region (Step S05).

Next, the optimization portion 25 determines whether or not optimization, for example, with respect to all of the plurality of parameters is completed (Step S06). When the determination result is “YES”, the optimization portion 25 advances the process to Step S07. On the other hand, when the determination result is “NO”, the optimization portion 25 causes the process to return to Step S04.

Next, the diagnosis portion 26 acquires a diagnosis value relating to the degradation state of the secondary battery 11, for example, based on the OCV curve estimated after the optimization of the plurality of parameters by the optimization portion 25 (Step S07). Then, the diagnosis portion 26 advances the process to the end.

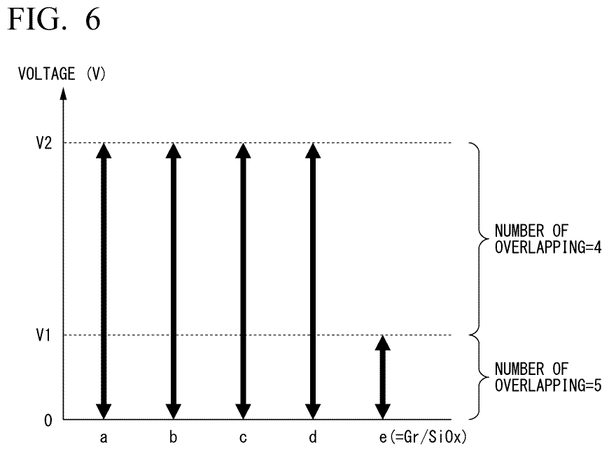

FIG. 6 is a view showing an example of a voltage region that contributes to a shape change of the OCV curve in each of a plurality of parameters relating to the state of the secondary battery 11 according to the embodiment.

For example, the positive electrode active material of the secondary battery 11 according to an example shown in FIG. 6 is a nickel-cobalt-aluminum oxide (NCA: LiNiₓCo_{y}AlₓO₂), and the negative electrode active material is a mixed material of graphite and a silicon oxide (SiOₓ). As shown in FIG. 6, for example, in a first voltage region from zero to a first voltage V1 including a discharge end stage (or a degradation end stage), among a plurality of parameters, five parameters by a positive electrode enlargement-reduction ratio a, a positive electrode shift amount b, a negative electrode enlargement-reduction ratio c, a negative electrode shift amount d, and an active material capacity ratio e develop the capacity characteristic. The active material capacity ratio e is, for example, a capacity ratio (=Gr/SiOₓ) by graphite (Gr) and a silicon oxide (SiOₓ) at the negative electrode. The number of overlapping of the parameter in the first voltage region is five. For example, in a second voltage region from the first voltage V1 to a second voltage V2, among the plurality of parameters, four parameters by the positive electrode enlargement-reduction ratio a, the positive electrode shift amount b, the negative electrode enlargement-reduction ratio c, and the negative electrode shift amount d develop the capacity characteristic. The number of overlapping of the parameter in the second voltage region is four.

In this case, the optimization portion 25 first performs the predetermined optimization process on the positive electrode enlargement-reduction ratio a, the positive electrode shift amount b, the negative electrode enlargement-reduction ratio c, and the negative electrode shift amount d based on the history data in the second voltage region. Next, the optimization portion 25 performs the predetermined optimization process on the active material capacity ratio e based on the history data in the first voltage region.

As described above, according to the system 1 including the secondary battery state estimation device 10 of the embodiment, by including the optimization portion 25 that performs the predetermined optimization process on the parameter sequentially and exclusively selected from the plurality of parameters, even when the number of parameters increases, it is possible to prevent a decrease in an estimation accuracy of an internal state of the secondary battery 11. For example, compared to the case where the predetermined optimization process is performed on all of the plurality of parameters in a collective manner instead of a gradual manner, each parameter can be uniquely acquired, and it is possible to stabilize each parameter and improve the estimation accuracy.

Since the optimization portion 25 performs the predetermined optimization process in each voltage region or each capacity region where the capacity characteristic of each parameter is developed, it is possible to improve the estimation accuracy of each parameter, for example, compared to the case where the predetermined optimization process is performed in a region where the capacity characteristic of each parameter is not developed.

Since a region to be processed is exclusively selected from the plurality of voltage regions or the plurality of capacity regions associated with the plurality of parameters in the order of a smaller number of overlapping of different parameters, it is possible to stabilize each parameter and improve the estimation accuracy.

For example, even when silicon in which the capacity characteristic develops at a discharge end stage (or a degradation end stage) is contained in the negative electrode of the secondary battery 11, it is possible to improve the estimation accuracy of the degradation degree of the negative electrode.

### Modification Example

Hereinafter, modification examples of the embodiment is described. The same parts as those in the embodiment described above are denoted by the same reference numerals, and descriptions thereof are omitted or simplified.

The above embodiment is described using an example in which the secondary battery state estimation device 10 is constituted of the server 3; however, the embodiment is not limited thereto. For example, at least one of the processes performed by the server 3 may be performed by the battery control portion 13 of the vehicle 2. That is, the secondary battery state estimation device 10 may be constituted of the server 3 and the battery control portion 13 or only of the battery control portion 13.

The above embodiment is described using an example in which the plurality of parameters include the positive electrode capacity a, the positive electrode position b, the negative electrode capacity c, the negative electrode position d, and the active material capacity ratio e; however, the present invention is not limited thereto. The plurality of parameters may include, for example, another parameter such as a voltage correction parameter. For example, the voltage correction parameter is a parameter that corrects the shape of the OCP curve or the OCV curve or the like.

In the embodiment described above, the positive electrode position b or the negative electrode position d among the plurality of parameters may be, for example, a relative position of the negative electrode OCP curve relative to the positive electrode OCP curve, a relative position of the positive electrode OCP curve relative to the negative electrode OCP curve, or the like.

The above embodiment is described using an example in which the OCP curve and the OCV curve are changes of the open circuit potential (OCP) or the open circuit voltage (OCV) in accordance with the discharge capacity x (Ah); however, the embodiment is not limited thereto. For example, a parameter relating to the capacity such as a charge capacity (Ah), the remaining capacity (SOC: State of Charge), or the depth of discharge (DOD: Depth of Discharge) may be used instead of the discharge capacity (Ah). The change tendency of the open circuit potential (OCP) or the open circuit voltage (OCV) is reversed between the discharge capacity (Ah) and the charge capacity (Ah).

For example, a capacity region having a predetermined discharge capacity or more corresponds to a capacity region having a predetermined charge capacity or less.

A program for realizing all or some of the functions of the system 1 including the secondary battery state estimation device 10 in the present invention may be recorded in a computer-readable recording medium, the program recorded in the recording medium may be read into and executed by a computer system, and thereby, all or some of the processes performed by the system 1 may be performed. It is assumed that the term “computer system” used herein includes an OS or hardware such as peripherals. Further, it is also assumed that the term “computer system” includes a WWW system which includes a homepage-providing environment (or a display environment). Further, the term “computer-readable recording medium” refers to a portable medium such as a flexible disk, a magneto-optical disk, a ROM, and a CD-ROM and a storage device such as a hard disk embedded in the computer system. Further, it is also assumed that the term “computer-readable recording medium” includes a medium which holds a program for a given time such as a volatile memory (RAM) in the computer system which becomes a server or a client when a program is transmitted through a network such as the Internet or a communication line such as a telephone line.

Further, the program may be transmitted from the computer system which stores the program in the storage device or the like to another computer system through a transmission medium or through transmission waves in the transmission medium. Here, the term “transmission medium” which transmits the program refers to a medium having a function of transmitting information that is, for example, a network (communication network) such as the Internet or a communication line such as a telephone line. Further, the program may be a program for realizing some of the above-described functions. Further, the program may be a so-called differential file (differential program) which can realize the above-described functions by a combination with a program already recorded in the computer system.

These embodiments of the present invention have been presented as examples and are not intended to limit the scope of the invention. These embodiments can be implemented in a variety of other modes, and various omissions, substitutions, and changes can be made without departing from the scope of the invention. These embodiments and modifications thereof are included in the scope and gist of the invention and are also included in the scope of the invention described in the appended claims and equivalent thereof.

What is claimed is:

1. A secondary battery state estimation system comprising:
a degradation estimation portion that acquires a plurality of parameters relating to a state of a secondary battery to be estimated based on voltage data which is acquired in the secondary battery to be estimated or which is acquired by data acquired in a secondary battery and thereby estimates a degradation degree of the secondary battery to be estimated,
wherein based on a predetermined association between the plurality of parameters and a plurality of voltage regions or a plurality of capacity regions, the degradation estimation portion sequentially acquires at least one parameter exclusively selected from the plurality of parameters for each of the plurality of voltage regions or the plurality of capacity regions.

2. The secondary battery state estimation system according to claim 1,
wherein the degradation estimation portion associates each of the plurality of parameters with a voltage region or a capacity region in which each of the parameters develops a capacity characteristic among the plurality of voltage regions or the plurality of capacity regions as the predetermined association.

3. The secondary battery state estimation system according to claim 1,
wherein when a number of parameters associated with a first voltage region by the predetermined association is less than a number of parameters associated with a second voltage region that is different from the first voltage region, the degradation estimation portion acquires, in the first voltage region before the second voltage region, a parameter associated with the first voltage region.

4. The secondary battery state estimation system according to claim 2,
wherein when a number of parameters associated with a first voltage region by the predetermined association is less than a number of parameters associated with a second voltage region that is different from the first voltage region, the degradation estimation portion acquires, in the first voltage region before the second voltage region, a parameter associated with the first voltage region.

5. The secondary battery state estimation system according to claim 1,
wherein when a number of parameters associated with a first capacity region by the predetermined association is less than a number of parameters associated with a second capacity region that is different from the first capacity region, the degradation estimation portion acquires, in the first capacity region before the second capacity region, a parameter associated with the first capacity region.

6. The secondary battery state estimation system according to claim 2,
wherein when a number of parameters associated with a first capacity region by the predetermined association is less than a number of parameters associated with a second capacity region that is different from the first capacity region, the degradation estimation portion acquires, in the first capacity region before the second capacity region, a parameter associated with the first capacity region.

7. The secondary battery state estimation system according to claim 1,
wherein the plurality of parameters comprises a parameter relating to a degradation degree of silicon contained in a negative electrode of the secondary battery to be estimated.

8. A secondary battery state estimation method performed by an electronic apparatus comprising a process portion that estimates a degradation degree of a secondary battery to be estimated, the method including:
acquiring a plurality of parameters relating to a state of the secondary battery to be estimated based on voltage data which is acquired in the secondary battery to be estimated or which is acquired by data acquired in a secondary battery; and
based on a predetermined association between the plurality of parameters and a plurality of voltage regions or a plurality of capacity regions, sequentially acquiring at least one parameter exclusively selected from the plurality of parameters for each of the plurality of voltage regions or the plurality of capacity regions.

9. A computer-readable non-transitory recording medium that records a program causing a computer of an electronic apparatus comprising a process portion that estimates a degradation degree of a secondary battery to be estimated to execute:
acquiring a plurality of parameters relating to a state of the secondary battery to be estimated based on voltage data which is acquired in the secondary battery to be estimated or which is acquired by data acquired in a secondary battery; and
based on a predetermined association between the plurality of parameters and a plurality of voltage regions or a plurality of capacity regions, sequentially acquiring at least one parameter exclusively selected from the plurality of parameters for each of the plurality of voltage regions or the plurality of capacity regions.
